(19) United States
(12) Patent Application Publication
(10) Pub. No.: US 2006/0228466 A1
(43) Pub. Date: Oct. 12, 2006

(54) Solution dispense and patterning process and apparatus

(76) Inventors: Gang Yu, Santa Barbara (CA); Gordana Srdanov, Santa Barbara, CA (US); Jorma Peltola, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/296,932

(22) Filed: Dec. 8, 2005

Related U.S. Application Data
(60) Provisional application No. 60/640,500, filed on Dec. 30, 2004.

(51) Int. Cl. B05D 5/12; B05D 5/06; B05D 5/00; B05D 1/02

(52) U.S. Cl. 427/64; 427/421.1; 427/256

(57) ABSTRACT

A liquid media is dispensed by a precision stream onto a substrate to form a pattern. The precision stream is controlled by pressure, liquid media composition, orifice size. Additionally, other factors such as height from the orifice form the substrate and a relative movement between the precision stream and the substrate control characteristics of the pattern disposed on the substrate.

### STATEMENT AS TO FEDERALLY SPONSORED RESEARCH

This invention was made with Government support under DARPA grant number 4332. The Government may have certain rights in the invention.

### FIELD OF THE DISCLOSURE

The invention relates generally to patterning substrates, organic materials, and organic electronic devices, and more specifically, to organic materials and their application to substrates to form patterns.

### BACKGROUND INFORMATION

Organic electronic devices have attracted increasing attention in recent years. Examples of organic electronic devices include Organic Light-Emitting Diode (“OLED”) displays. Current research in the production of full-color OLED displays is directed toward the development of cost effective, high throughput processes for producing full-color displays. For the manufacture of monochromatic displays, spin-coating processes have been widely adopted. However, manufacture of full-color displays usually requires certain modifications to procedures used in the manufacture of monochromatic displays. For example, to make a display with full-color images, each display pixel is divided into three subpixels, each emitting one of the three primary colors: red, green, and blue. This division of each display pixel into three subpixels has resulted in a need to modify current processes for depositing different organic materials onto a single substrate during the manufacture of OLED displays.

One such process for making organic electronic devices is to deposit organic material layers on a substrate by inkjet printing. In a conventional inkjet process, the liquid composition of the ink drops includes an organic material in a solution, dispersion, emulsion, or suspension with an organic solvent or with an aqueous solvent. After deposition, the solvent evaporates and the organic material remains to form a layer for the organic electronic device.

Many challenges exist, however, in using inkjet processing for making organic electronic devices. For example, to achieve high resolution in an OLED display, each subpixel must be relatively small. This in turn requires that each inkjet droplet be relatively small. Typically, for achieving high resolution, the droplet volume ranges between a few tenths of a picoliter to a few picoliters. When the volume of the droplet is so small, volume fluctuations among different droplets become significant. In addition, for display applications, the requirement of homogeneity among near neighbor pixels is rigorous. Typically, homogenicity values of between 0.5%-2% are required for a display with 6 to 8 bit digital gray levels. Thus, precise volumetric control of each droplet is crucial.

In a second example, due to the small volume and mass of each droplet, the control of delivery of the droplets to pre-defined locations becomes critical. The trajectory of each droplet is affected by the process environment such as airflow, the moving condition of the inkjet head, and the like. Thus, fluctuations in spatial accuracy become a significant problem. In addition, with display pixel pitch sizes typically in the 50-500 micron range, the accuracy requirement of delivering droplets to pre-defined locations on the substrate could require accuracy to within a few microns. Since step-motors or servo-motors are typically used to drive the nozzle head when inkjet printing, and since they are frequently driven with a controlling system using digitized motion steps, synchronizing and positioning a droplet correctly presents a major challenge.

In a third example, for such small droplet volumes, the diameter of the nozzle head is relatively small: ˜10-50 microns. Nozzle clogging becomes a common issue. Nozzle maintenance (reliability, repeatability, frequency and process down time) also becomes crucial when used in a manufacturing environment.

In a fourth example, a display typically contains about 10⁵-10⁶ pixels. Repeating the inkjet process with the requirements above 10⁶ times for a single display without error is an extremely difficult task but is required for a manufacturing process. Even with sophisticated inkjet equipment using complex process controls for the rigorous process conditions above, yields remain low. Thus, inkjet processing currently faces challenges for manufacturing of organic electronic devices.

It can readily be seen that conventional inkjet printing has several disadvantages and problems. Therefore, an alternative printing technology that can achieve the required performance with simplicity and reliability is needed.

### SUMMARY

The invention includes a process for forming an organic electronic device includes forming a first patterned organic layer over a substrate using a precision stream deposition technique.

In another aspect of the invention, the precision stream is formed with a nozzle having an orifice with the orifice having a diameter ranging from 50 to 200 microns.

In another aspect of the invention, the first patterned organic layer includes a line with a width ranging from 60 to 420 microns.

In another aspect of the invention, the line has a thickness ranging from 40 to 150 microns.

In another aspect of the invention, the precision stream has a relative motion to the substrate ranging from 100 to 600 millimeters per second.

In another aspect of the invention, the substrate includes a bank.

In another aspect of the invention, the precision stream is formed from a low viscosity fluid

In another aspect of the invention, the low viscosity fluid is pressurized in a range from 0.1 to 10.0 pounds per square inch.

The foregoing general description and the following detailed description are exemplary and explanatory only and are not restrictive of the invention, as defined in the appended claims.

### BRIEF DESCRIPTION OF THE FIGURES

The invention is illustrated by way of example and not limitation in the accompanying figures.

FIG. 1 illustrates a schematic representation of a precision dispensing system for depositing a fluid in a pattern on a substrate using a precision stream;

FIGS. 2 and 3 illustrate side sectional and end sectional views of an enlarged portion of a nozzle, a substrate, and a precision stream;

FIGS. 4-7 illustrate sectional views of an electroluminescent device in partial degrees of fabrication; and

FIGS. 8-10 illustrate additional sectional views of an electroluminescent device in partial degrees of fabrication.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The present invention provides a process for patterning a substrate with a liquid media. The pattern is generated by forming a precision stream which deposits a layer of liquid media on the substrate while there is relative motion between the precision stream and the substrate.

### Definitions and Clarification of Terms

Before addressing details of embodiments described below, some terms are defined or clarified.

As used herein, the term “active” when referring to a layer or material is intended to mean a layer or material that exhibits electronic properties, electro-radiative properties, or a combination thereof. An active layer material may emit radiation or exhibit a change in concentration of electron-hole pairs when responding to radiation.

The terms “array,” “peripheral circuitry” and “remote circuitry” are intended to mean different areas or components of the organic electronic device. For example, an array may include a number of pixels, cells, or other structures within an orderly arrangement (usually designated by columns and rows). The pixels, cells, or other structures within the array may be controlled locally by peripheral circuitry, which may lie within the same organic electronic device as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “bank” is intended to mean a wall or a portion of a wall that can confine liquid media to a defined area. A bank may be a part of a well structure.

The term “continuous” when referring to a layer is intended to mean a layer that covers an entire substrate or portion of a substrate (e.g., the array) without any breaks in the layer. Note that a continuous layer may have a portion that is locally thinner than another portion and still be continuous if there is no break or gap in the layer.

The term “emission maximum” is intended to mean the highest intensity of radiation emitted. The emission maximum has a corresponding wavelength or spectrum of wavelengths (e.g. red light, green light, or blue light).

The term “organic electronic device” is intended to mean a device including one or more organic semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “orifice” is intended to mean an opening though which a liquid media passes. The orifice can be any suitable shape such as circular, oval, rectangular, elliptical, or the like. When the orifice is an oval, rectangle, or ellipse, the opening can be any suitable ratio of length to width depending upon the specific application.

The term “oblong” is intended to refer to a two-dimensional shape characterized by a length and a width that are not equal to each other. Examples of oblong shapes include rectangles, ovals, ellipses, etc.

The term “diameter” is intended to mean the distance across an orifice when the orifice is circular in shape.

The term “primary surface” refers to a surface of a substrate from which electronic components are fabricated.

The phrase “room temperature” is intended to mean a temperature in a range of approximately 20-25° C.

The term “well structure” refers to a structure used to confine a liquid during processing. A well structure may also be called a dam, a divider, or a frame.

The term “blue light” is intended to mean radiation that has a wavelength in a range of approximately 400-500 nm.

The term “green light” is intended to mean radiation that has a wavelength in a range of approximately 500-600 nm.

The term “low viscosity fluid” is intended to mean a fluid that minimally resists flowing or minimally resist changes in the rate of shear forces. Thus, a low viscosity fluid has a tendency to spread quickly when applied to a substrate as referred to in this application. Typically, with reference to the viscosity of the fluid that forms a precision stream, several ranges of low viscosity can be considered. A first low viscosity range extends from approximately 1.0 to 15.0 centipoise (cps), with a second low viscosity range extending from approximately 3.0 to 10.0 cps.

The term “patterned” when referring to a layer is intended to mean a layer that covers at least a portion of a substrate with a breaks in the layer. A patterned layer can form a connected pattern, such as a lattice, or a disconnected pattern, such as a series of parallel strips that do not contact each other, or can be a combination thereof so as to form any geometric shape.

The term “precision stream” is intended to mean a controlled continuous stream of liquid media or fluid that is exiting though an orifice.

The term “precision stream deposition technique” is intended to mean a liquid deposition technique, wherein at least a part of an organic layer is formed from a liquid solution that is deposited in a continuous stream to form a desired pattern. Features of the pattern formed by a precision stream deposition technique can be characterized by, for instance, lines of liquid solution with uniform widths on the scale of the height or width of an individual pixel of an array of pixels. An inkjet process, where discrete volumes of liquid are deposited in a discontinuous manner, is not a precision stream deposition technique.

The term “radiation-emitting component” is intended to mean an electronic component, which when properly biased, emits radiation at a targeted wavelength or spectrum of wavelengths. The radiation-emitting component is typically characterized as having an emission maximum at the targeted wavelength. The emitted radiation may be within the visible-light spectrum or outside the visible-light spectrum (ultraviolet (“UV”) or infrared (“IR”)). A light-emitting diode is an example of a radiation-emitting component.

The term “red light” is intended to mean radiation that has a wavelength in a range of approximately 600-700 nm.

The term “radiation-responsive component” is intended to mean an electronic component, which when exposed to radiation, produces carriers (i.e., electrons and holes). The radiation-responsive component may or may not be designed for radiation at a targeted wavelength or spectrum of wavelengths to be within the visible-light spectrum or outside the visible-light spectrum (UV or IR). IR sensors and photovoltaic cells are examples of radiation-responsive components.

The term “liquid media” is intended to mean any fluid or combination of fluids and solids that is used in the precision stream deposition technique wherein the liquid media forms a precision stream which is applied to the substrate to form a pattern.

The term “substrate” is intended to mean a base material and all layer(s), member(s), and structure(s) present over the base material at a particular point in a process. For example, before any processing occurs, the substrate and the base material may be the same. However, before forming an organic active layer, a substrate may include the base material, first electrodes, a charge transport layer, and other peripheral circuitry.

The term “visible light spectrum” is intended to mean a radiation spectrum having wavelengths corresponding to approximately 400-700 nm.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present). Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Group numbers corresponding to columns within the periodic table of the elements use the “New Notation” convention as seen in the CRC Handbook of Chemistry and Physics, 81^{st} Edition (2000).

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductor arts.

### DETAILED DESCRIPTION

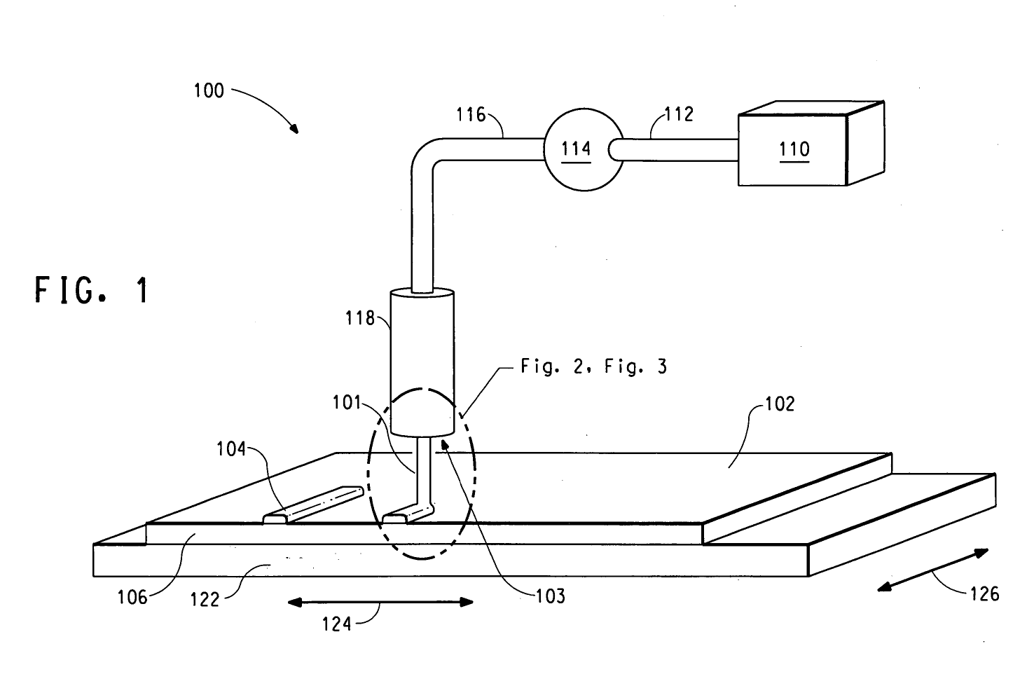

FIG. 1 illustrates a simplified schematic representation of a precision dispensing system 100 for depositing a liquid media in a pattern, illustrated by pattern 104, on a substrate 106 using a precision stream 101. Precision dispensing system 100 includes several parts such as a reservoir 110 for holding the liquid media, manifold devices 112 and 116 for distributing the liquid media, a pressure device 114 for pressurizing the liquid media, a nozzle 118 having an orifice 103 for dispensing the liquid media, and a substrate holding device 122. It should be understood that elements having the same or similar characteristics will retain their original numerical identification.

Reservoir 110 schematically illustrates a system for retaining the liquid media, in such quantity, to supply precision dispensing system 100. Reservoir 110 can be any suitable type of holding device or container that is chemically compatible with various parts of precision dispensing system 100 and the chemistries and materials of substrate 106. Generally, reservoir 110 can be made of any suitable non reactive material such as certain types of metal materials, plastic materials, suitable combinations thereof, or the like.

It should be noted that any suitable liquid media can be used in conjunction with precision dispensing system 100. However, it should be understood that selection of the liquid media is application specific depending upon user requirements and constraints imposed by the material systems.

Fluid manifold devices 112 and 116 illustrate the operable connection from reservoir 110 to pressure device 114 and from pressure device 114 to nozzle 118. However, it should be understood that fluid manifold devices 112 and 116 can be much more complicated than is illustrated. For example, fluid manifold devices 112 and 116 can include one or more filtering devices installed or embedded therein, other inputs and outputs, or the like. Additionally, other manifold systems can be also installed as required. Fluid manifold devices 112 and 116 are made of any suitable materials. Typically, these materials are made from non-reactive organic or metallic materials such as polypropylene, stainless steel, or the like.

Nozzle 118 illustrates a simplified schematic system for generating a precision stream 101 though orifice 103. It should be understood that nozzle 118 can be much more complicated than is illustrated and that many complicating details have been omitted for the sake of clarity. Generally, nozzle 118 can be made capable of movement along the x, y, and z axes by any suitable method such as electromechanically, hydraulically, pneumatically, or the like. However, it should be noted that movement of nozzle 118 is application specific and can vary from system to system. For example, in some systems, the design may require only a movement in the x axis with y axis movement being done by a substrate holding device 122. Generally, nozzle 118 is capable of moving so that any desired characteristics for making a pattern, illustrated by pattern 104, can be optimized. Additionally, while only a single nozzle 118 is illustrated, it should be understood that additional nozzles can also be used so as to facilitate pattern generation, illustrated by pattern 104, and use of other liquid media. For example, a row of nozzles can be assembled such that the nozzles can be independently moved or tied together depending upon the specific application.

Substrate 106 receives the liquid media from precision stream 101 though orifice 103. Substrate 106 can be made of any suitable material. These materials can be broadly grouped as dielectric, conductive, or semiconductive materials. Examples of dielectric materials include, but are not limited to, glass materials, plastic materials, and the like. Examples of conductive materials include, but are not limited to, metal materials and alloys, such as gold, copper, silver, and the like. Examples of semiconductive material include, but are not limited to, silicon, gallium arsenide, sapphire, and the like. It should also be understood that substrate 106 can have been previously processed, thereby forming other patterns, electrical and mechanical devices, a number of different material incorporated therein, and the like.

Substrate holding device 122 is made to hold substrate 106. Substrate holding device 122 can be made by any suitable method or technique. Typically, substrate holding device 122 takes the form of an x-y stage, a platen, or a chuck. Movement of the x-y stage is illustrated by arrows 124 and 126. It should be understood that in some embodiments, substrate holding device 122 can also move in the z axis. Typically, substrate 106 is secured to substrate holding device 122 either by drawing a vacuum on a backside of substrate 106, mechanically clamping substrate 106, or the like.

It should be understood that substrate holding device 122 can be electromechanically engaged so that it can move independently of nozzle 118. By enabling both substrate holding device 122 and nozzle 118 to be able to move, a more robust process can be achieved to produce a pattern, illustrated by pattern 104. The movement of substrate holding device 122 is illustrated by arrows 124 and 126.

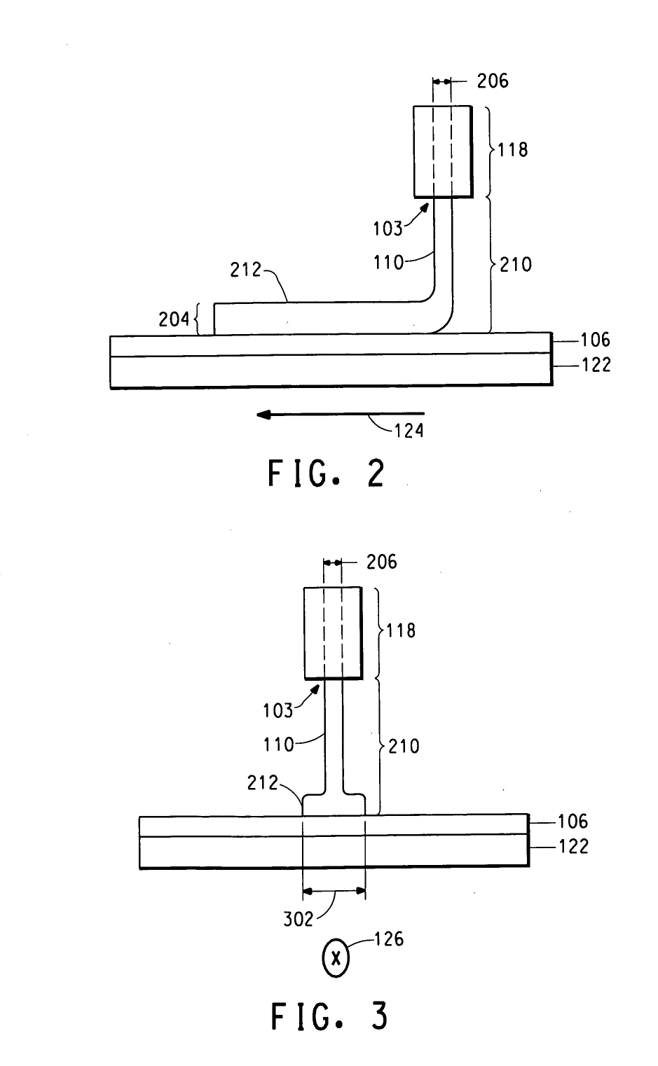

FIGS. 2 and 3 illustrate simplified, and greatly enlarged, side and end sectional views, respectively, of the dashed circle as illustrated in FIG. 1. Referring to FIGS. 2 and 3 together, FIG. 2 illustrates a simplified side sectional view of an enlarged portion of nozzle 118 with orifice 103 positioned at a height 210 from substrate 106. A precision stream 101 flows from orifice 103 with a subsequent deposition of a patterned layer 212 on substrate 10, the patterned layer 212 having a thickness 204 and width 302. Control of patterned layer 212 is achieved by controlling precision stream 101, distance 210, and a relative movement between precision stream 101 and substrate 106.

Precision stream 101 is made by controlling several factors including pressure, viscosity of the liquid media, a size 206, such as a diameter, of orifice 103, and a shape of orifice 103. Additionally, other factors controlling patterned layer 212 include a distance 210 between orifice 103 and substrate 106, and a relative speed of precision stream 101 to substrate 106, which interacts with precision stream 101 to form patterned layer 212.

A pressure is applied to the liquid media to force the liquid media though orifice 103 to form precision stream 101. Pressure is applied to the liquid media by any suitable method, such as backing with a non reacting gas, use of constant pressure fluid pumps, or the like. By keeping the liquid media under a constant pressure, patterned layer 212 is more consistent, repeatable, and subsequently more robust. Typically, while any suitable pressure can be used, the liquid media generally is held at a pressure between 1.0 and 7.0 pounds per square inch. However, depending upon the liquid media composition and other factors such as temperature and the like, the liquid media pressure can be held between 0.1 to 10.0 pounds per square inch.

It should be understood that one or more liquid media compositions may be used for making the liquid media. Liquid media compositions contemplated for use in the practice of the invention are chosen so as to provide proper solution characteristics for the material system at hand and the desired results. Factors to be considered when choosing a liquid media composition include, for example, viscosity of the resulting solution, emulsion, suspension, or dispersion, molecular weight of a polymeric material, solids loading, type of solvent (e.g., organic based or aqueous based compositions), vapor pressure of the liquid medium, temperature of an underlying substrate, thickness of an organic layer that receives a guest material, the interactions between co-solvents if more than one solvent is used, or any combination thereof.

In addition, when selecting various liquid media compositions, care needs to be exercised because one particular component of the liquid media may or may not be compatible with other components of the liquid media and/or organic layers on which the liquid media is being deposited.

In some embodiments, the liquid media includes at least one organic solvent. Exemplary organic solvents include halogenated solvents, hydrocarbon solvents, aromatic hydrocarbon solvents, ether solvents, cyclic ether solvents, alcohol solvents, ketone solvents, nitrile solvents, sulfoxide solvents, amide solvents, and combinations thereof.

Exemplary halogenated solvents include carbon tetrachloride, methylene chloride, chloroform, tetrachloroethylene, chlorobenzene, bis(2-chloroethyl)ether, chloromethyl ethyl ether, chloromethyl methyl ether, 2-chloroethyl ethyl ether, 2-chloroethyl propyl ether, 2-chloroethyl methyl ether, and combinations thereof.

Exemplary hydrocarbon solvents include pentane, hexane, cyclohexane, heptane, octane, decahydronaphthalene, petroleum ethers, ligroine, and combinations thereof.

Exemplary aromatic hydrocarbon solvents include benzene, naphthalene, toluene, xylene, ethyl benzene, cumene (iso-propyl benzene) mesitylene (trimethyl benzene), ethyl toluene, butyl benzene, cymene (iso-propyl toluene), diethylbenzene, iso-butyl benzene, tetramethyl benzene, sec-butyl benzene, tert-butyl benzene, and combinations thereof.

Exemplary ether solvents include diethyl ether, ethyl propyl ether, dipropyl ether, disopropyl ether, dibutyl ether, methyl t-butyl ether, glyme, diglyme, benzyl methyl ether, isochroman, 2-phenylethyl methyl ether, n-butyl ethyl ether, 1,2-diethoxyethane, sec-butyl ether, diisobutyl ether, ethyl n-propyl ether, ethyl isopropyl ether, n-hexyl methyl ether, n-butyl methyl ether, methyl n-propyl ether, and combinations thereof.

Exemplary cyclic ether solvents suitable include tetrahydrofuran, dioxane, tetrahydropyran, 4 methyl-1,3-dioxane, 4-phenyl-1,3-dioxane, 1,3-dioxolane, 2-methyl-1,3-dioxolane, 1,4-dioxane, 1,3-dioxane, 2,5-dimethoxytetrahydrofuran, 2,5-dimethoxy-2,5-dihydrofuran, and combinations thereof.

Exemplary alcohol solvents include methanol, ethanol, 1-propanol, 2-propanol, 1-butanol, 2-butanol, 2-methyl-1-propanol (i.e., iso-butanol), 2-methyl-2-propanol (i.e., tert-butanol), 1-pentanol, 2-pentanol, 3-pentanol, 2,2-dimethyl-1-propanol, 1-hexanol, cyclopentanol, 3-methyl-1-butanol, 3-methyl-2-butanol, 2-methyl-1-butanol, 2,2-dimethyl-1-propanol, 3-hexanol, 2-hexanol, 4-methyl-2-pentanol, 2-methyl-1-pentanol, 2-ethylbutanol, 2,4-dimethyl-3-pentanol, 3-heptanol, 4-heptanol, 2-heptanol, 1-heptanol, 2-ethyl-1-hexanol, 2,6-dimethyl-4-heptanol, 2-methylcyclohexanol, 3-methylcyclohexanol, 4-methylcyclohexanol, and combinations thereof.

Alcohol ether solvents may also be employed. Exemplary alcohol ether solvents include 1-methoxy-2-propanol, 2-methoxyethanol, 2-ethoxyethanol, 1-methoxy-2-butanol, ethylene glycol monoisopropyl ether, 1-ethoxy-2-propanol, 3-methoxy-1-butanol, ethylene glycol monoisobutyl ether, ethylene glycol mono-n-butyl ether, 3-methoxy-3-methylbutanol, ethylene glycol mono-tert-butyl ether, and combinations thereof.

Exemplary ketone solvents include acetone, methylethyl ketone, methyl iso-butyl ketone, cyclohexanone, isopropyl methyl ketone, 2-pentanone, 3-pentanone, 3-hexanone, diisopropyl ketone, 2-hexanone, cyclopentanone, 4-heptanone, iso-amyl methyl ketone, 3-heptanone, 2-heptanone, 4-methoxy-4-methyl-2-pentanone, 5-methyl-3-heptanone, 2-methylcyclohexanone, diisobutyl ketone, 5-methyl-2-octanone, 3-methylcyclohexanone, 2-cyclohexen-1-one, 4-methylcyclohexanone, cycloheptanone, 4-tert-butylcyclohexanone, isophorone, benzyl acetone, and combinations thereof.

Exemplary nitrile solvents include acetonitrile, acrylonitrile, trichloroacetonitrile, propionitrile, pivalonitrile, isobutyronitrile, n-butyronitrile, methoxyacetonitrile, 2-methylbutyronitrile, isovaleronitrile, N-valeronitrile, n-capronitrile, 3-methoxypropionitrile, 3-ethoxypropionitrile, 3,3′-oxydipropionitrile, n-heptanenitrile, glycolonitrile, benzonitrile, ethylene cyanohydrin, succinonitrile, acetone cyanohydrin, 3-n-butoxypropionitrile, and combinations thereof.

Exemplary sulfoxide solvents suitable include dimethyl sulfoxide, di-n-butyl sulfoxide, tetramethylene sulfoxide, methyl phenyl sulfoxide, and combinations thereof.

Exemplary amide solvents suitable include dimethyl formamide, dimethyl acetamide, acylamide, 2-acetamidoethanol, N,N-dimethyl-m-toluamide, trifluoroacetamide, N,N-dimethylacetamide, N,N-diethyldodecanamide, epsilon-caprolactam, N,N-diethylacetamide, N-tert-butylformamide, formamide, pivalamide, N-butyramide, N,N-dimethylacetoacetamide, N-methyl formamide, N,N-diethylformamide, N-formylethylamine, acetamide, N,N-diisopropylformamide, 1-formylpiperidine, N-methylformanilide, and combinations thereof.

Crown ethers contemplated include all crown ethers which can function to assist in the reduction of the chloride content of an epoxy compound starting material as part of the combination being treated according to the invention. Exemplary crown ethers include benzo-15-crown-5; benzo-18-crown-6; 12-crown-4; 15-crown-5; 18-crown-6; cyclohexano-15-crown-5; 4′,4″(5″)-ditert-butyldibenzo-18-crown-6; 4′,4″(5″)-ditert-butyldicyclohexano-18-crown-6; dicyclohexano-18-crown-6; dicyclohexano-24-crown-8; 4′-aminobenzo-15-crown-5; 4′-aminobenzo-18-crown-6; 2-(aminomethyl)-15-crown-5; 2-(aminomethyl)-18-crown-6; 4′-amino-5′-nitrobenzo-15-crown-5; 1-aza-12-crown-4; 1-aza-15-crown-5; 1-aza-18-crown-6; benzo-12-crown-4; benzo-15-crown-5; benzo-18-crown-6; bis((benzo-15-crown-5)-15-ylmethyl)pimelate; 4-bromobenzo-18-crown-6; (+)-(18-crown-6)-2,3,11,12-tetra-carboxylic acid; dibenzo-18-crown-6; dibenzo-24-crown-8; dibenzo-30-crown-10; ar-ar′-di-tert-butyidibenzo-18-crown-6; 4′-formylbenzo-15-crown-5; 2-(hydroxymethyl)-12-crown-4; 2-(hydroxymethyl)-15-crown-5; 2-(hydroxymethyl)-18-crown-6; 4′-nitrobenzo-15-crown-5; poly-[(dibenzo-18-crown-6)-co-formaldehyde]; 1,1-dimethylsila-11-crown-4; 1,1-dimethylsila-14-crown-5; 1,1-dimethylsila-17-crown-5; cyclam; 1,4,10,13-tetrathia-7,16-diazacyclooctadecane; porphines; and combinations thereof.

In another embodiment, the liquid media includes water. A conductive polymer complexed with a water-insoluble colloid-forming polymeric acid can be deposited over a substrate and used as a charge transport layer.

Liquid media can include many different classes of materials (e.g., halogenated solvents, hydrocarbon solvents, aromatic hydrocarbon solvents, aqueous solvents, etc.) which are described above. Mixtures of more than one of the materials from different classes may also be used.

By mixing the appropriate solvent and other components, a suitable composition of the liquid media having the proper solution characteristics is made.

Orifice 103 is illustrated having a circular shape with a diameter 206. However, depending upon the application, orifice 103 can be made with any suitable shape such as oval, elliptical, or the like. By way of example only, with orifice 103 having a circular shape, diameter 206 can range between 10 to 300 microns. In another, example, diameter 206 can range between 50 to 150 microns. In yet another example, diameter 206 can range between 75 to 125 microns. In yet another example, orifice 103 is shaped into an oval or an ellipse that is configured such that a ratio of approximately 4:1 (length to width) is formed.

Generally, distance 210 between orifice 103 and primary surface 102 of substrate 106 can be any suitable distance. However, it should be understood that distance 210 is application specific and can change depending upon the specific application and the interplay between the other factors. Typically, however, distance 210 can range from 10 to 300 microns or may range from 20 to 150 microns depending upon the application, and in some instance can range from 60 to 100 microns. By adjusting distance 210, characteristics of patterned layer 212 can be altered. For example, as distance 210 increases, width 302 of patterned layer 212 tends to decrease. Conversely, as distance 210 decreases, width 302 of patterned layer 212 tends to increase.

Generating a relative movement between precision stream 101 and substrate 106 can be accomplished by any suitable method such as having substrate 106 move, nozzle 118 move, or any combination thereof. By generating relative movement between precision stream 101 and substrate 106, patterned layer 212 is adjusted. By way of example, with patterned layer 212 being a line, by increasing the speed at which the relative movement occurs, width 302 of line decreases. Conversely, decreasing the speed at which the relative movement occurs, width 302 increases.

Use of precision stream 101 has several unexpected and unique advantages such as being able to deposit long lines of liquid media without causing contamination defects from splashing or air currents. Additionally, because stream 101 is continuously flowing during deposition, a more cost-effective alternative is provided that allows a more consistent and reproducible placement of the liquid media on the substrate 106. Further, since orifice 103 of nozzle 118 is not made of consumable items, a cost saving is realized in long term up time and replacement costs.

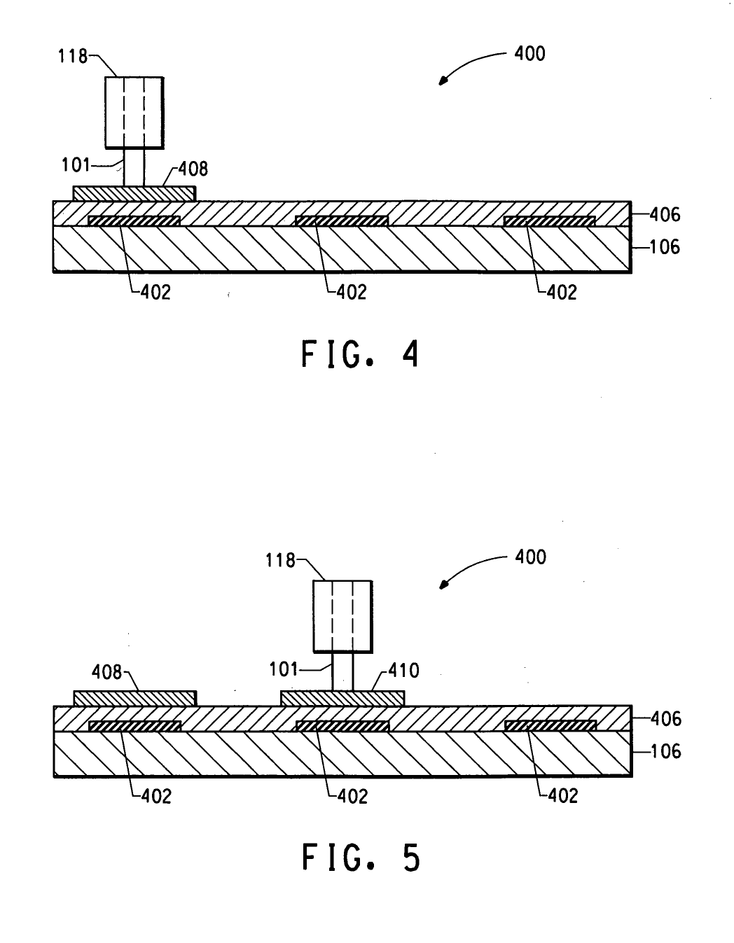

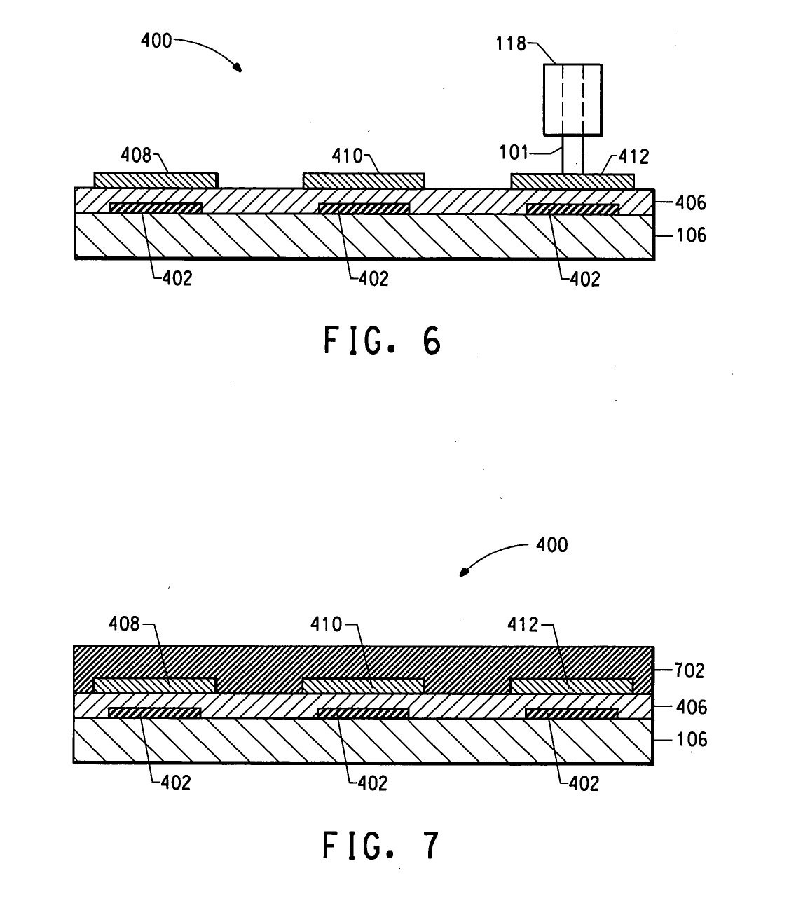

In one embodiment, FIGS. 4-7 illustrate sectional views of a pixel 400 in partial degrees of fabrication. While only a single pixel is illustrated, it should be understood that many pixels are populated on substrate 106 forming a pixel array in order to make a display. It should also be understood that FIGS. 4-7 can extend into an out of the drawings. Pixel driver and other circuits (not illustrated) may be formed within or over substrate 106 using any suitable conventional technique. The other circuits (not illustrated) outside the array may include peripheral and remote circuitry used to control the pixels within the array. The focus of fabrication is on the pixel array rather than the peripheral or remote circuitry. While any suitable thickness of substrate 106 can be used, substrate 106 typically can be of any thickness in a range of approximately 12-2500 microns.

Referring now to FIG. 4, first electrodes 402 are formed over portions of substrate 106. First electrodes 402 act as anodes and may include one or more conductive layers. The surface of first electrodes 402 furthest from the substrate 106 includes a high work function material. In this illustrative example, the first electrodes 402 include one or more of layers of indium tin oxide, aluminum tin oxide, or other materials conventionally used for anodes within organic electronic devices. In this embodiment, first electrodes 402 transmit at least 70% of the radiation to be emitted from or responded to by subsequently formed organic active layers 408, 410, and 412. In one embodiment, the thickness of the first electrodes 402 is in a range of approximately 100-200 nm. However, if radiation does not need to be transmitted through the first electrodes 402, the thickness may be greater, such as up to 1000 nm or even thicker.

First electrodes 402 can be formed using any suitable method, technique, or combination thereof including conventional coating, vapor deposition (chemical or physical), printing (inkjet printing, screen printing, solution dispense, or any combination thereof), other deposition techniques, or any combination thereof. In one embodiment, the first electrodes 402 may be formed as a patterned layer (e.g., using a stencil mask) or by depositing the layer(s) over all the substrate 106 and using a conventional patterning technique which exposes certain portions while protecting other portions of the layer(s). The exposed portions of the layer(s) are then removed by any suitable method and cleaned, thereby resulting in the patterned layer(s).

Organic layer 406 can be formed over the first electrodes 402 as illustrated in FIG. 4. The organic layer 406 may include one or more layers. For example, the organic layer 406 may include a charge transport layer or other layers and materials that can aid in the movement of charge into an active area. However, it should also be understood that in some applications the charge transport layer does not need to be incorporated into the device. Also, it should be noted that when the charge transport layers lay between the first electrodes 402, that act as anodes, and the organic active layers 408, 410, and 412, the charge transport layers will be a hole-transport layer, and when the charge transport layer lies between the organic active layers 408, 410, and 412 and subsequently formed second electrode 702, as illustrated in FIG. 7, that act as cathodes, the charge transport layers will be an electron-transport layer. The configuration as illustrated in FIG. 4 has organic layer 406 acting as the charge transport layer that acts as the hole-transport layer.

Organic layer 406 can be formed by one or more of any number of different techniques including spin coating, vapor depositing (chemical or physical), printing (inkjet printing, screen printing, solution dispensing, or any combination thereof), other depositing or any combination thereof for appropriate materials as described below. Additionally, one or both of the organic layer(s) 406 and the organic active layer(s) 408, 410, and 412 may be cured after deposition.

In addition to facilitating transport of charge from the first electrodes 402 to organic active layers 408, 410, and 412, the charge transport layer may also function as a charge injection layer facilitating injection of charged carriers into the organic active layers 408, 410, and 412, a planarization layer over the first electrodes 402, a passivation or chemical barrier layer between the first electrodes 402 and organic active layers 408, 410, and 412, or any combination thereof.

When organic layer 406 acts as the charge transport, any number of materials may be used (and its selection will depend on the device and the organic active layers 408, 410, and 412 material) and in this illustrative example, it may include one or more of polyaniline (“PANI”), poly(3,4-ethylenedioxythiophene) (“PEDOT”) or material(s), and tetrcyanoquinodimethane(TTF-TCQN), and the like conventionally used as hole-transport layers as used in organic electronic devices. The hole-transport layer typically has a thickness in a range of approximately 100-250 nm as measured over the substrate 106 at a location spaced apart from the first electrodes 402.

As illustrated in FIGS. 4-7, organic layer 406 is substantially continuous over first electrodes 402. In one embodiment, the organic layer 406 may be substantially continuous over the entire substrate, including the peripheral and remote circuitry areas. Note that organic layer 406 has regions where organic layer 406 is locally thinner, but it is not discontinuous over the area of substrate 106 in which organic layer 406 is intended to be formed (e.g., the array). Referring to FIGS. 4-7, the organic layer 406, including the charge transport layers, is locally thinner over the first electrodes 402 and locally thicker away from the first electrodes 402. The organic layer 406 typically has a thickness in a range of approximately 50-500 nm as measured over the substrate 106 at a location spaced apart from the first electrodes 402.

Organic active layers 408, 410, and 412 are deposited on certain portions of organic layer 406 which overlay portions of first electrodes 402. Deposition of organic active layers 408, 410, and 412 is achieved by forming precision stream 101 from orifice 103 of nozzle 118 and developing a relative motion between precision stream 101 and substrate 106. Depending upon the specific application, it should be understood that any suitable velocity of relative motion between precision stream 101 and substrate 106 can be used. However, several velocity ranges of relative motion between the precision stream 101 and substrate 106 can be identified, with one range being from 100 to 1,000 millimeters per second and a second range being from 150 to 800 millimeters per second.

By way of example only, with the pattern generated being a line, with liquid media having a relative motion with a viscosity that ranges from 1 to 15 cps, with the pressure ranging on the liquid media from 1.0 psi to 10.0 psi, with orifice 103 being circular and having a diameter ranging from 10 microns to 300 microns, with distance 210 ranging between 10.0 millimeters and 300.0 millimeters, and with the relative speed ranging from 100 to 1,000 millimeter per second, line widths ranging from 60 to 420 microns with thicknesses ranging from 10 to 150 nanometers can be generated. By changing the above parameters to more median values, line widths and thickness can be moderated. For example, by controlling the relative motion velocity from 150 to 800 millimeters per second, line widths can range from 80 microns to 400 microns with thicknesses ranging from 30 to 90 microns. In another example, by controlling the distance 210 between 20 to 150 millimeters, line widths can range from 100 to 200 microns. It should be understood by one of ordinary skill in the art that an enormous number of combinations can be used to elicit the desired effect.

For example, with the liquid media being selected so as to produce a red light upon excitation, the liquid media is deposited over first electrode 402 by precision stream 101 from orifice 103 and having a relative motion between precision stream 101 and substrate 106. Thus, a red light line is formed on substrate 106 having certain thickness and width characteristics.

Further, this deposition procedure in the proper position for a green light and a blue light liquid media lines can be exemplified by organic active layers 410 and 412, respectively.

The composition of organic active layers 408, 410, and 412 typically depends upon the application of the organic electronic device. In the embodiment illustrated in FIGS. 4-7, the organic active layers 408, 410, and 412 are used in radiation-emitting components. Organic active layer 408, 410, and 412 can include material(s) as conventionally used as organic active layers in organic electronic devices and can include one or more small molecule materials, one or more polymer materials, or any combination thereof. After reading this specification, skilled artisans will be capable of selecting appropriate material(s), layer(s) or both for the organic active layers 408, 410, and 412.

For a radiation-emitting organic active layer, suitable radiation-emitting materials include one or more small molecule materials, one or more polymeric materials; or a combination thereof. Small molecule materials may include those described in, for example, U.S. Pat. No. 4,356,429 (“Tang”); U.S. Pat. No. 4,539,507 (“Van Slyke”); U.S. Patent Application Publication No. US 2002/0121638 (“Grushin”); and U.S. Pat. No. 6,459,199 (“Kido”). Alternatively, polymeric materials may include those described in U.S. Pat. No. 5,247,190 (“Friend”); U.S. Pat. No. 5,408,109 (“Heeger”); and U.S. Pat. No. 5,317,169 (“Nakano”). Exemplary materials are semiconducting conjugated polymers. Examples of such polymers include poly(paraphenylenevinylene) (PPV), PPV copolymers, polyfluorenes, polyphenylenes, polyacetylenes, polyalkylthiophenes, poly(n-vinylcarbazole) (PVK), and the like. In one specific embodiment, a radiation-emitting active layer without any other materials may emit blue light.

For a radiation-responsive organic active layer, suitable radiation-responsive materials may include many conjugated polymers and electroluminescent materials. Such materials include for example, many conjugated polymers and electro- and photo-luminescent materials. Specific examples include poly(2-methoxy,5-(2-ethyl-hexyloxy)-1,4-phenylene vinylene) (“MEH-PPV”) and MEH-PPV composites with CN-PPV.

Materials can include any one or more of all known materials used for an electroluminescent layer, charge transport (e.g., hole transport, electron transport) layer, or other materials used for organic active layer and their corresponding dopants. Such materials can include organic dyes, organometallic materials, polymers (conjugated, partially conjugated, or non-conjugated), and combinations thereof. The guest materials may or may not have fluorescent or phosphorescent properties.

Examples of the organic dyes include 4-dicyanmethylene-2-methyl-6-(p-dimethyaminostyryl)-4H-pyran (DCM), coumarin, pyrene, perylene, rubrene, derivatives thereof, and combinations thereof.

Examples of organometallic materials include functionalized polymers comprising functional groups coordinated to at least one metal. Exemplary functional groups contemplated for use include carboxylic acids, carboxylic acid salts, sulfonic acid groups, sulfonic acid salts, groups having an OH moiety, amines, imines, diimines, N-oxides, phosphines, phosphine oxides, β-dicarbonyl groups, and combinations thereof. Exemplary metals contemplated for use include lanthanide metals (e.g., Eu, Tb), Group 7 metals (e.g., Re), Group 8 metals (e.g., Ru, Os), Group 9 metals (e.g., Rh, Ir), Group 10 metals (e.g., Pd, Pt), Group 11 metals (e.g., Au), Group 12 metals (e.g., Zn), Group 13 metals (e.g., Al), and combinations thereof. Such organometallic materials include metal chelated oxinoid compounds, such as tris(8-hydroxyquinolato)aluminum (Alq₃); cyclometalated iridium and platinum electroluminescent compounds, such as complexes of iridium with phenylpyridine, phenylquinoline, or phenylpyrimidine ligands as disclosed in Published PCT Application WO 02/02714, and organometallic complexes described in, for example, published applications US 2001/0019782, EP 1191612, WO 02/15645, WO 02/31896, and EP 1191614; and mixtures thereof.

Examples of conjugated polymers include poly(phenylenevinylenes), polyfluorenes, poly(spirobifluorenes), copolymers thereof, and mixtures thereof.

When used for the production of full-color organic electronic devices, in one embodiment, a first material is selected to emit red light (with an emission maximum in a range of 600-700 nm), a second material is selected to emit green light (with an emission maximum in a range of 500-600 nm), and a third material is selected to emit blue light (with an emission maxium in a range of 400-500 nm). After placement of each of the liquid media, each pixel column contains three subpixels wherein one subpixel emits red light, one subpixel emits green light, and one subpixel emits blue light. Alternatively, one or more materials can be contained in a single liquid media composition and deposited to form a pixel or subpixel with a broader emission spectrum, for example with a Full Width Half Maximum (FWHM) of greater than 100 nm, or even selected to emit white light with an emission profile encompassing the visible spectrum of 400 to 700 nm.

Although not illustrated, an optional charge transport layer that acts as an electron-transport layer may be formed over the organic active layers 408, 410, and 412. The optional charge transport layer may include at least one of Alq₃ or other material conventionally used as electron-transport layers in organic electronic devices. The optional charge transport layer can be formed by one or more of any number of different techniques including spin coating, vapor deposition (chemical or physical), printing (inkjet printing, screen printing, solution dispense, or any combination thereof), other depositing technique, or any combination for appropriate materials as described below. The electron-transport layer typically has a thickness in a range of approximately 30-500 nm as measured over the substrate 106 at a location spaced apart from the first electrodes 402.

A second electrode 702 is formed over organic layer 406 and organic active layers 408, 410, and 412 as illustrated in FIG. 7. In this specific embodiment, second electrode 702 acts as a common cathode for an array. A surface of the second electrode 702 includes a low work function material. Second electrode 702 includes one or more of a Group 1 metal, Group 2 metal, or other materials conventionally used for cathodes within organic electronic devices.

Second electrode 702 can be formed using any suitable method, technique, or combination of techniques including a conventional coating, vapor deposition (chemical or physical), printing (inkjet printing, screen printing, solution dispense, or any combination thereof), or other deposition technique, or any combination thereof. Second electrode 702 can be formed as a patterned layer (e.g., using a shadow mask) or by depositing one or more of several layers over the entire array and using a conventional patterning sequence. Second electrode 702 has a thickness in a range of approximately 100-2000 nm. It should also be understood that second electrode 702 can also be made in the form of having a plurality of electrodes.

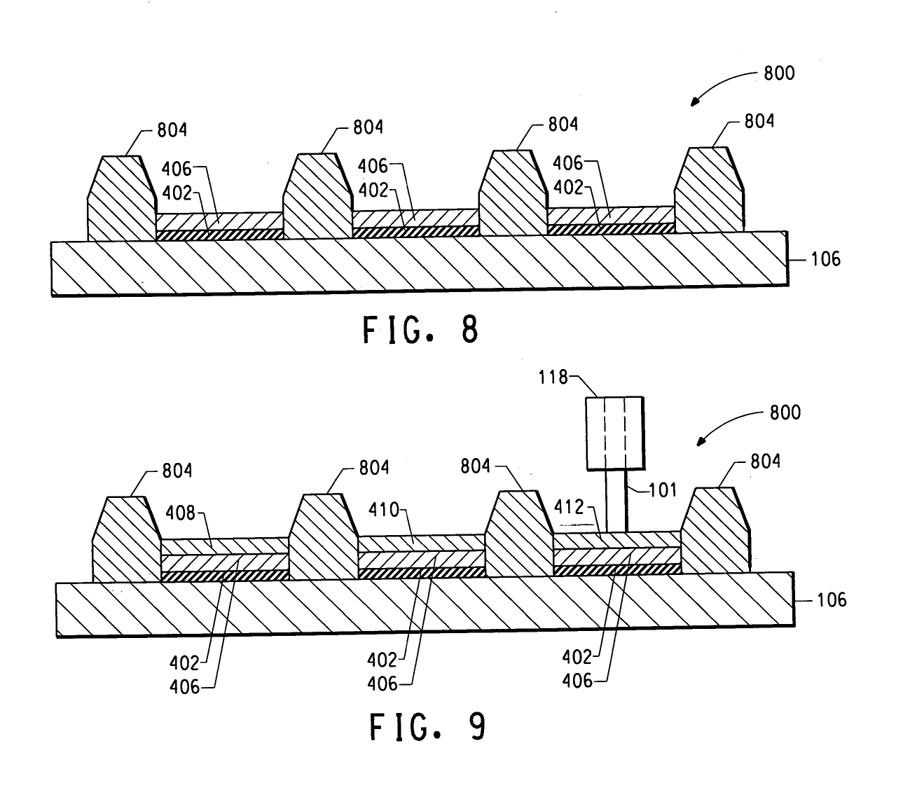

In one embodiment, FIGS. 8-10 illustrate a greatly enlarged sectional view of a pixel 800 in partial degrees of fabrication. Pixel 800 incorporates banks 804 which further form well structures (not illustrated). While only a single pixel 800 is illustrated, it should be understood that many pixels are populated on substrate 106 forming a pixel array so as to form a display. It should be further understood that that FIGS. 8-10 can extend into and out of the drawings, thereby forming arrays of pixels. Additionally, other circuits (not illustrated) outside the array may include peripheral and remote circuitry used to control the pixels within the array. The focus of the fabrication is on pixel 800 and on the array rather then the peripheral or remote circuitry.

Referring now to FIG. 8, a partially fabricated pixel 800 is illustrated. Banks 804 are made on substrate 106 to separate individual pixels 800 and subpixels. Banks 804 are made by any suitable method, technique, or combination of techniques including, but not limited to, photolithography, etching, deposition, and the like. Banks 804 can be made of any suitable dielectric material such as an organic material, an inorganic material, or the like. By way of example, banks 804 are made with a depositing a photoresist material on substrate 106. The photoresist is then pattern and developed such that portions of photoresist remain on the substrate 106 while other portions of substrate 106 are exposed. The remaining photoresist on substrate 106 become banks 804. Alternatively and by way of example, an oxide layer could be deposited or grown, photo lithographically patterned, and etched, thereby forming a bank 804 or well structure of oxide. By way of example only, banks 804 can range from 5-30 microns in width with a thickness ranging from 1 to 3 microns.

First electrodes 402 and organic layer 406 are made and function as previously described in FIGS. 4-7 and need not be discussed in detail.

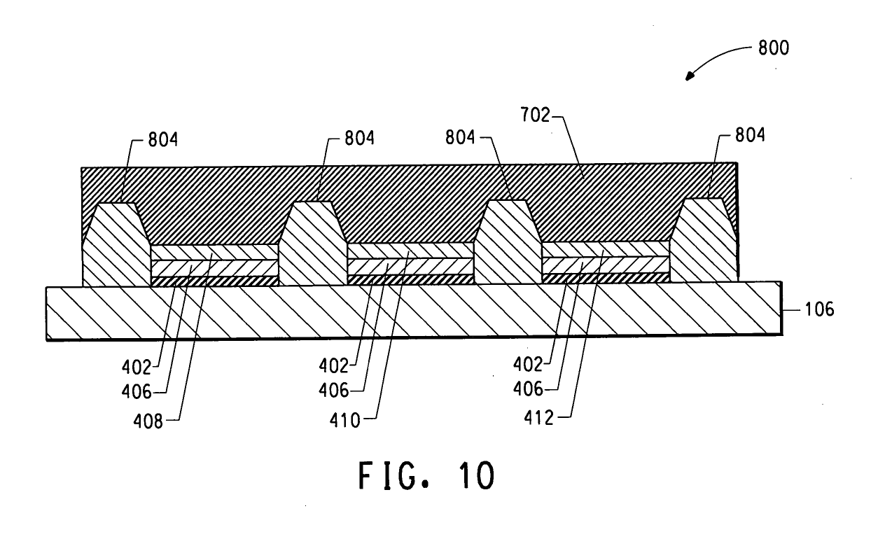

FIG. 9 illustrates pixel 800 further along in the fabrication process. Selection of materials for organic active layers 408, 410, and 412 have been discussed previously in FIGS. 4-7. Referring to FIG. 9, organic active layers 408 and 410 have already been deposited over organic layer 406 and first electrodes 402. Organic active layer 412 illustrates deposition of the selected liquid media though orifice 103 with precision stream 101 over organic layer 406 and first electrodes 402. The process for selecting and depositing liquid media over substrate 106 is discussed in more detail in FIGS. 4-7.

FIG. 10 illustrates pixel 800 with second electrode 702 formed over substrate 106. Formation of second electrode 702 is discussed in detail in FIG. 7. Generally, second electrode 702 can be formed by any suitable method or technique, or combination thereof including conventional coating, vapor deposition (chemical or physical), printing (inkjet printing, screen printing, solution dispense, or any combination thereof), other deposition techniques, or any combination thereof.

With reference to FIGS. 4-10, other circuitry not illustrated in FIGS. 4-10 can be formed using any number of the previously described or additional layers. Although not illustrated, additional insulating layer(s) and interconnect level(s) can be formed to allow for circuitry in peripheral areas (not illustrated) that may lie outside the array. Such circuitry may include row or column decoders, strobes (e.g., row array strobe, column array strobe), or sense amplifiers. Alternatively, such circuitry may be formed before, during, or after the formation of any layers illustrated in FIGS. 4-10.

Typically, after second electrode 702 is formed, a lid (not illustrated) with a desiccant (not illustrated) is attached to the substrate 106 at locations (not shown) outside the array to form a substantially completed device. A gap (not illustrated) lies between the second electrode 702 and the desiccant (not illustrated). The materials used for the lid (not illustrated) and desiccant (not illustrated) and the attaching process are conventional.

Generally, with organic active layer 408 being properly configure for emitting red, with organic active layer 410 being properly configured for green, and with organic active layer 412 being properly configured for emitting blue, applying an appropriate potential between first electrode 402 and second electrode 702 causes radiation to be emitted from organic active layers 408, 410, and 412. Furthermore, the potentials and current used for the radiation-emitting components may be adjusted to change the intensity of color emitted from such components to achieve nearly any color within the visible light spectrum.

### EXAMPLES

The invention will be further described in the following examples, which do not limit the scope of the invention described in the claims.

All substrates for examples 1 and 2 were prepared in the following manner. With a substrate 106 made of glass and with first electrodes 402 being patterned and made of ITO, the substrate 106 was cleaned with deionized (DI) water and subsequently spin dried. Substrate 106 was then treated with an oxygen plasma for ten (10) minutes at 300 watts at 5×10⁻³ torr.

### Example 1

In a first example, a liquid composition included an electroluminescent polymer with a greenish-yellow emission having a molecular weight of approximately 500,000. The pressure of a constant pressure device was set at approximately 5 pounds per square inch (psi). The orifice 103 of nozzle 118 was circular and had a diameter of approximately 190 microns and was set approximately 50 microns above substrate 106. The relative motion of the nozzle 118 to the substrate 106 was approximately 500 mm/sec.

With these parameters, lines were produced having a width ranging from approximately 350 to 400 microns and having a thickness ranging from approximately 50 nm to 200 nm.

### Example 2

In a second example, all parameters were the same as in the Example 1, except that the pressure of the constant pressure device was set at approximately 2 psi and the orifice 103 had a diameter of approximately 150 microns. Lines were produced with a width ranging from approximately 300 to 350 microns and a thickness ranging from approximately 70 to 100 microns.

### Example 3

In a third example, with substrate 106 being prepared as in Example 1, a non-patterned hole-transport layer (Baytron-P, CH8000, Bayer AG, Germany) was spin coated onto substrate 106 and baked at 120 degrees Centigrade for 60 minutes, thereby forming a substantially continuous layer of approximately 100 nanometers. Subsequently, a non-patterned layer of a polyfluorene-based blue electroluminescent material was spun over the Baytron-P layer with a thickness of approximately 75 nanometers. This non-patterned blue layer acts as a receiving layer, or host, for subsequently deposited emissive layers, which can diffuse into the receiving layer, and affects the formation of the emissive layers.

A liquid media was prepared as an electroluminescent polymer with a greenish emission having a molecular weight of approximately 500,000. The liquid media was made with toluene at a concentration of 2-5 mg/ml (2-5 mg of the polymer to 1 ml of the solvent) and with a viscosity of approximately 10 cps. Orifice 103 of nozzle 118 had a circular shape and a diameter of approximately 125 microns and was set at distance, illustrated by distance 210, ranging from approximately 25 to 100 microns above substrate 106. Relative motion of nozzle 118 to substrate 106 was approximately 500 mm/sec.

With a pump designed for low viscosity fluid dispensing at a constant pressure (EFD 740Vmade by Nordson) installed, the pressure was kept at a constant pressure on individual runs, but was varied between 2 and 5 psi.

With these parameters, lines were deposited having a width ranging from approximately 180 to 200 microns with a thickness ranging from approximately 70 to 200 microns. Generally, it is believed that with this approximate set up line widths of approximately 1.5 times the diameter of orifice 103 can be achieved. It was also found that when the receiving layer, in this case the blue electroluminescent material, is soluble to the solvent used in the liquid media, a wider line is formed.

### Example 4

In a fourth example, with substrate 106 being prepared and treated as in Example 3 and with the a first set of lines (not illustrated) being deposited and dried, a second line (not illustrated) was deposited perpendicular to the first line, thereby generating intersections between the first and second lines. It was found in this example that the line width of the second line was reduced by approximately ten percent (10%) over the intersections of the first and second lines.

### Example 5

In a fifth example, with substrate 106 being prepared and treated as in Example 3, distance 210 between orifice 103 and substrate 106 was varied from 25 to 150 microns. It was found that as distance 210 increased the width of the deposited line increased.

### Example 6

In a sixth example, with substrate 106 being prepared and treated as in Example 3, orifice 103 having a circular shape and a diameter of approximately 90 microns was used to deposit green electroluminescent material. The green electroluminescent lines had a width of about 130 microns. It should be noted that pitches used in full-color high definition televisions (HDTVs) with 65 pixels per inch (ppi) are approximately equivalent to the line width as demonstrated. Thus, this process could be used to manufacture HDTVs. It should also be noted that needles or nozzles (e.g. manufactured by ProSciTech, Queensland, Australia) are commercially available with orifice 103 in a circular shape and having diameters from 10 microns and larger.

### Example 7

In a seventh example, with substrate 106 being prepared and treated as in Example 3 and with green electroluminescent lines deposited on substrate 106, a barium/aluminum (Ba/Al) cathode was deposited over a non-patterned blue electroluminescent host material with lines of green electroluminescent guest material to make a display. The display was then encapsulated with epoxy and glass and the electroluminescent emission was tested. The emission test showed a uniform emission pattern of the green electroluminescent lines 104.

### Example 8

In an eighth example, with substrate 106 being prepared and treated as in Example 3 and with both green and red electroluminescent lines deposited over substrate 106, a barium/aluminum (Ba/Al) cathode was deposited over the non-patterned blue electroluminescent host material with lines of both green and red electroluminescent guest material to make a display. The display was then encapsulated with epoxy and glass and the electroluminescent emission was tested. The emission test showed a uniform emission pattern along the green and red deposited lines.

### Example 9

In a ninth example, an aqueous-based liquid composition was used and the orifice 103 of nozzle 118 was coated with a Teflon™ material having similar dimensions as describe above. Similar tests with similar results were obtained with this equipment variation.

Thus, the forgoing examples illustrate the usefulness that a continuous stream process in several configurations can be used to pattern substrates that are used in making organic light emitting displays.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1. A process for forming an organic electronic device comprising forming a patterned organic layer over a substrate using a precision stream, wherein:
the precision stream is formed with a nozzle having an orifice; and
the patterned organic layer comprises a line having a width in a range of approximately 60 to 420 microns and a thickness in a range of approximately 10 to 150 nanometers.

2. The process of claim 1, wherein the orifice has a circular shape, wherein the circular shape has a diameter in a range of approximately 10 to 300 microns.

3. The process of claim 2, wherein the diameter is in a range of approximately 50 to 150 microns.

4. The process of claim 3, wherein the diameter is in a range of approximately 75 to 125 microns.

5. The process of claim 1, wherein the width is in a range of approximately 80 to 400 microns.

6. The process of claim 5, wherein the width is in a range of approximately 100 to 200 microns.

7. The process of claim 1, wherein the thickness is in a range of approximately 30 to 90 nanometers.

8. The process of claim 1, wherein the nozzle has a relative motion to the substrate in a range of approximately 100 to 1,000 nanometers per second.

9. The process of claim 8, wherein the relative motion is in a range of approximately 150 to 800 nanometers per second.

10. The process of claim 1, wherein the orifice has an oblong shape.

11. The process of claim 10, wherein the oblong shape has a ratio of length to width of about 4 to 1.

12. An electronic device formed by the process of claim 1.

13. A method for depositing a liquid composition comprising an organic active material, the method comprising:
providing a substrate;
pressurizing the liquid composition at a constant pressure with a constant pressure device, wherein an input of the constant pressure device is operably coupled with the liquid composition; and
depositing the liquid composition on the surface of the substrate through a nozzle with an orifice using a precision stream, wherein the orifice is a distance from the substrate in a range of approximately 10 to 300 microns.

14. The method of claim 13, wherein the constant pressure is in a range of approximately 0.1 to 10.0 pounds per square inch.

15. The method of claim 14, wherein the constant pressure is in a range of approximately 1.0 to 7.0 pounds per square inch.

16. The method of claim 13, wherein the distance from the substrate is in a range of approximately 20 to 150 microns.

17. The method of claim 16, wherein the distance from the substrate is in a range of approximately 60 to 100 microns.

18. The method of claim 13, wherein the pattern has a shape of a line with a width ranging from 80 to 400 microns.

19. The method of claim 18, wherein the width is in a range of approximately 100 to 200 microns.

20. The method of 13, wherein the orifice is a plurality of orifices.

21. The method of claim 13, further comprising moving the nozzle across the substrate with a relative motion, wherein the relative motion is in the range of approximately 100 to 1,000 millimeters per second.

22. An electronic device formed by the process of claim 13.
